(19) United States
(12) Patent Application Publication
(10) Pub. No.: US 2005/0116765 A1
(43) Pub. Date: Jun. 2, 2005

(54) Semiconductor integrated circuit

(75) Inventors: Shiro Sakiyama, Yawata-shi (JP); Masayoshi Kinoshita, Osaka (JP); Masaya Sumita, Amagasaki-shi (JP)

Correspondence Address: MCDERMOTT WILL & EMERY LLP, 600 13TH STREET, N.W., WASHINGTON, DC, 20005-3096, US

(73) Assignee: MATSUSHITA ELECTRIC INDUSTRIAL CO., LTD.

(21) Appl. No.: 10/994,552

(22) Filed: Nov. 23, 2004

(30) Foreign Application Priority Data
Nov. 28, 2003 (JP) 2003-399522

(51) Int. Cl. H03K 3/037

(52) U.S. Cl. 327/534

(57) ABSTRACT

In a semiconductor integrated circuit, respective semiconductor circuits are disposed in different regions partitioned in accordance with their operation probabilities per unit time, and a supply voltage and a threshold voltage are correlatively controlled in each region. A target value for controlling the threshold voltage is determined in accordance with the operation probability of the semiconductor circuit. A threshold voltage control circuit controls substrate voltages of p-type and n-type MOS transistors included in the semiconductor circuit so that the threshold voltage can be constant at the target value regardless of the temperature change occurring in use. Simultaneously, a supply voltage control circuit controls the supply voltage for the semiconductor circuit so that an objective operating frequency can be attained. As a result, a semiconductor integrated circuit with low power consumption can be obtained.

### CROSS-REFERENCE TO RELATED APPLICATIONS

This application claims priority under 35 U.S.C. §119(a) on Patent Application No. 2003-399522 filed in Japan on Nov. 28, 2003, the entire contents of which are hereby incorporated by reference.

### BACKGROUND OF THE INVENTION

The present invention relates to a power management technique employed for operating a semiconductor integrated circuit composed of MOS transistors with lower power consumption.

In order to operate a semiconductor integrated circuit composed of MOS transistors with lower power consumption, power management means through supply voltage control or threshold voltage control have been conventionally proposed.

Among these means, the supply voltage control has now been put to practical use, and control for changing a supply voltage correspondingly to each operating frequency is carried out by the technical name of “X-scale” of Intel Corporation, “Long Run” of Transmeta Corporation or “Power Now!” of Advance Micro Devices, Inc. Also in Japan, similar techniques have been released by Toshiba Corporation, Sony Corporation and the like by their original names. Although a supply voltage set correspondingly to each operating frequency and voltage resolution are different among the techniques proposed by the respective corporations, the point is that a supply voltage corresponding to each operating frequency is lowered for performing an operation with lower power consumption commonly in all the techniques. This is because the operating power P of an LSI can be approximated by a formula, P=fCV² and hence it is the key to reduce the power consumption how the supply voltage V is lowered.

However, in order to realize a low voltage operation, it is necessary to also lower the threshold voltage Vt of a MOS transistor, and a new power problem has been arisen in accordance with a recently lowered threshold voltage of a MOS transistor. The problem is what is called a leakage current problem, and specifically, a leakage current is generally exponentially increased in proportion to lowering of the threshold voltage.

With respect to the threshold voltage control, a VTCMOS (Variable Threshold CMOS) technique is well known. Literally in this technique, a threshold voltage is changed by controlling substrate potential of a MOS transistor. The detailed technique and use are described in, for example, Nikkei Electronics, 1997, 7.28 (No. 695). In general, a leakage current is always constant regardless of an operation time or a stand-by time of a device, and hence, leakage power is conspicuous in the stand-by time as compared with operating power. Therefore, it is necessary to suppress the leakage power by controlling the threshold voltage to be higher during the stand-by time. Accordingly, in the VTCMOS, the substrate voltage of a MOS transistor is changed between the operation time and the stand-by time. Specifically, with two kinds of substrate voltages provided, larger back bias is given to the substrate in the stand-by time so as to attain a higher threshold voltage.

Also, the threshold voltage control has been proposed also for the purpose of suppressing variation. For example, Japanese Laid-Open Patent Publication No. 9-129831 describes threshold voltage control to be employed for correcting a shift of the threshold voltage of a MOS transistor from a set value caused by process variation. The disclosure is specifically described with reference to its representative drawing. A reference voltage VR1 with smaller variation than the threshold voltage of a MOS transistor is generated, and a substrate voltage Vbn of the MOS transistor is feedback controlled so that the threshold voltage of a representative MOS transistor, used as a process monitor, can accord with the reference voltage VR1. In this circuit, the temperature dependency characteristic of the threshold voltage of the MOS transistor is controlled to accord with the temperature dependency characteristic of the reference voltage VR1 (that is, the temperature dependency characteristic of a diode in this case).

In this manner, as the techniques to realize lower power consumption, the optimization of a supply voltage correspondingly to an operating frequency is widely known with respect to the supply voltage control, and the method for controlling a substrate voltage to be different between operating modes as known as the VTCMOS is widely known with respect to the threshold voltage control. Also, as the technique to suppress the threshold voltage variation, the method for controlling a substrate voltage of a transistor so as to make its threshold voltage equal to a reference voltage is known.

Thus, as the power management technique for operating a semiconductor integrated circuit composed of MOS transistors with lower power consumption, the supply voltage control and the threshold voltage control are regarded as leading means.

In these conventional techniques, however, the supply voltage control is mainly used for reducing power consumed in the operation time and the threshold voltage control is mainly used for reducing power consumed in the stand-by time. Therefore, the power is not effectively reduced by these conventional technique.

### SUMMARY OF THE INVENTION

An object of the invention is providing a semiconductor integrated circuit that can realize much lower power consumption than in the conventional techniques.

In order to achieve the object, according to the invention, supply voltage control and threshold voltage control are correlated with each other to be effectively used.

Specifically, the semiconductor integrated circuit of this invention includes a plurality of semiconductor circuits each of which is composed of a plurality of MOS transistors and which are disposed in regions partitioned in accordance with operation probabilities per unit time of the plurality of semiconductor circuits; a threshold voltage control circuit provided to each of the regions for controlling a threshold voltage of MOS transistors used by a semiconductor circuit disposed in the corresponding region; and a supply voltage control circuit provided to each of the regions for controlling a supply voltage supplied to a semiconductor circuit disposed in the corresponding region.

In one aspect of the semiconductor integrated circuit, the threshold voltage control circuit controls a substrate voltage of the MOS transistors in such a manner that the threshold voltage of the MOS transistors is substantially constant against temperature change occurring in use, and the supply voltage control circuit controls the supply voltage in such a manner that the semiconductor circuit disposed in the corresponding region attains a given operation speed.

In another aspect of the semiconductor integrated circuit, the threshold voltage control circuit controls the threshold voltage of the MOS transistors in accordance with the operation probability of the semiconductor circuit disposed in the corresponding region.

In still another aspect of the semiconductor integrated circuit, the supply voltage control circuit controls the supply voltage in such a manner that actual delay of the semiconductor circuit disposed in the corresponding region accords with target delay at a given operating frequency of the semiconductor circuit.

In still another aspect, the semiconductor integrated circuit further includes, correspondingly to each of the regions, a plurality of delay monitor circuits with different architectures for monitoring actual delay of the semiconductor circuit disposed in the corresponding region, and one of the plurality of delay monitor circuits is selected in accordance with a level of the threshold voltage of the MOS transistors controlled by the threshold voltage control circuit or a level of the supply voltage controlled by the supply voltage control circuit provided to the corresponding region.

In another aspect of the semiconductor integrated circuit, the supply voltage control circuit controls the supply voltage in such a manner that an actual saturation current value of the MOS transistors used by the semiconductor circuit disposed in the corresponding region accords with a target saturation current value of the MOS transistors at a given operating frequency of the semiconductor circuit.

In still another aspect of the semiconductor integrated circuit, the target saturation current value is set to be in proportion to an actual operation supply voltage of the semiconductor circuit.

In still another aspect of the semiconductor integrated circuit, the supply voltage control circuit uniquely controls the supply voltage on the basis of operating frequency information of the semiconductor circuits disposed in the corresponding region and temperature information.

In still another aspect of the semiconductor integrated circuit, the plurality of semiconductor circuits are fabricated in a given region, and the given region is previously partitioned into a high threshold region in which a threshold voltage of MOS transistors fabricated therein is high and a low threshold region in which a threshold voltage of MOS transistors fabricated therein is low.

In still another aspect of the semiconductor integrated circuit, a semiconductor circuit with a low operation probability per unit time is fabricated in the high threshold region and a semiconductor circuit with a high operation probability per unit time is fabricated in the low threshold region.

In still another aspect of the semiconductor integrated circuit, processors having an identical configuration are respectively fabricated in the high threshold region and the low threshold region, and processing with a high operation probability per unit time is allocated to the processor fabricated in the low threshold region.

As described so far, in the semiconductor integrated circuit according to the invention, a plurality of semiconductor circuits are disposed in regions partitioned in accordance with their operation probabilities per unit time, and in each of these regions, the optimization control of the supply voltage and the threshold voltage control of the MOS transistors are correlatively performed on a semiconductor circuit included in the corresponding region. For example, in a semiconductor circuit included in one region, a control target value of the threshold voltage of MOS transistors is determined correspondingly to the operation probability per unit time so as to attain low power consumption in the operation time, and the supply voltage is adjusted and controlled to have a minimum value for attaining the operating frequency of the semiconductor circuit included in the region while controlling an actual threshold voltage to be constant at the target value regardless of temperature change occurring in the operation time. Accordingly, the power consumption is largely reduced as compared with the conventional technique in which if the threshold voltage of MOS transistors is changed in accordance with the temperature change during the operation time of the semiconductor integrated circuit and the power consumption is increased due to the change of the threshold voltage, the supply voltage alone is controlled to be optimized to a minimum value under the changed threshold voltage.

### BRIEF DESCRIPTION OF THE DRAWINGS

FIG. 1 is a graph for showing a region where objective processing performance of a semiconductor integrated circuit is satisfied;

FIG. 2 is a graph for showing the relationship between a supply voltage and power consumption of a semiconductor integrated circuit;

FIG. 3 is a graph for showing a method for obtaining a supply voltage Vdd and a threshold voltage Vt for minimizing total power;

FIG. 4 is a graph for showing optimum values of the supply voltage Vdd and the threshold voltage Vt corresponding to each operation probability per unit time of a semiconductor circuit;

FIG. 5 is a graph for showing optimum values of the supply voltage Vdd and the threshold voltage Vt in accordance with temperature change;

FIG. 6A is a graph for showing total power obtained by optimizing the supply voltage Vdd and the threshold voltage Vt and total power obtained by optimizing the supply voltage alone in temperature change in an operation at 100 MHz and FIG. 6B is a graph for showing these total powers obtained in temperature change in an operation at 300 MHz;

FIG. 7 is a diagram for showing an example of region partition for semiconductor circuits;

FIG. 8 is a diagram for showing the internal architecture of one region resulting from the region partition;

FIG. 9 is a diagram for showing an example of the internal configuration of one semiconductor circuit;

FIG. 10 is a diagram for showing an exemplified configuration of a Vt control circuit according to an embodiment of the invention;

FIG. 11 is a diagram for showing an exemplified architecture of a Vdd control circuit of the embodiment;

FIG. 12 is a diagram for showing an exemplified internal configuration of a delay monitor circuit included in the Vdd control circuit;

FIG. 13 is a diagram for showing another exemplified internal configuration of the delay monitor circuit;

FIG. 14 is a diagram for showing an exemplified architecture of a selection circuit employed when two kinds of delay monitor circuits are used;

FIG. 15 is a diagram for showing another exemplified architecture of the Vdd control circuit of the embodiment;

FIG. 16 is a diagram for showing an exemplified internal configuration of an Ids monitor circuit included in the Vdd control circuit;

FIG. 17 is a diagram for showing another exemplified internal configuration of the Ids monitor circuit;

FIG. 18 is a diagram for showing still another exemplified architecture of the Vdd control circuit; and

FIG. 19 is a diagram for showing partition between a high threshold region and a low threshold region in the semiconductor integrated circuit according to the embodiment of the invention.

### DETAILED DESCRIPTION OF THE INVENTION

Preferred embodiments of the invention will now be described with reference to the accompanying drawings.

First, an operation speed theory for a MOS transistor circuit will be described. At this point, it is described that there is an operation boundary region in the relationship between a supply voltage Vdd and a threshold voltage Vt for attaining objective processing performance. Next, a power consumption theory for a MOS transistor circuit will be described. At this point, it is described that there is merely one combination of a supply voltage Vdd and a threshold voltage Vt for minimizing power consumption under conditions for attaining objective processing performance. Thereafter, optimum values of a supply voltage Vdd and a threshold voltage Vt are analyzed by using actual semiconductor parameters. Subsequently, control circuits for a supply voltage Vdd and a threshold voltage Vt based on a low power consumption effect and the analysis result will be described.

Operation Speed Theory

In general, a semiconductor circuit composed of MOS transistors can be operated faster as a supply voltage is higher or a threshold voltage of a MOS transistor is lower. Assuming that a parasitic capacitative element C of the semiconductor circuit is driven with a constant current source Id, a gate delay time r of the MOS transistor approximated as a time spent on attaining a supply voltage Vdd is represented by the following Formula 1:
τ=C·Vdd/Id Formula 1:

In a MOS transistor, the current source Id can be generally approximated as a saturation current formula of the following Formula 2:
Id=β(Vdd−Vt)^{α} Formula 2:

In this formula, β is a constant corresponding to (W/L)μCox, wherein μ is mobility, Cox is gate oxide film capacitance, W is a gate width of the MOS transistor and L is a gate length of the MOS transistor, and α is a constant depending upon process, which is said to typically have a value of approximately 1.5. Furthermore, assuming that the maximum number of gate stages between clocks in operating the semiconductor circuit is G and a frequency used for actually operating the semiconductor circuit is f, the gate delay time τ should fall in a region represented by the following Formula 3:
τ≦1/(f·G) Formula 3:

Accordingly, when Formulas 2 and 3 are assigned in Formula 1 and the resultant formula is solved for a threshold voltage Vt, the following Formula 4 is obtained:
Vt≦Vdd−(C·f·G·Vdd/β)^{1/α} Formula 4:

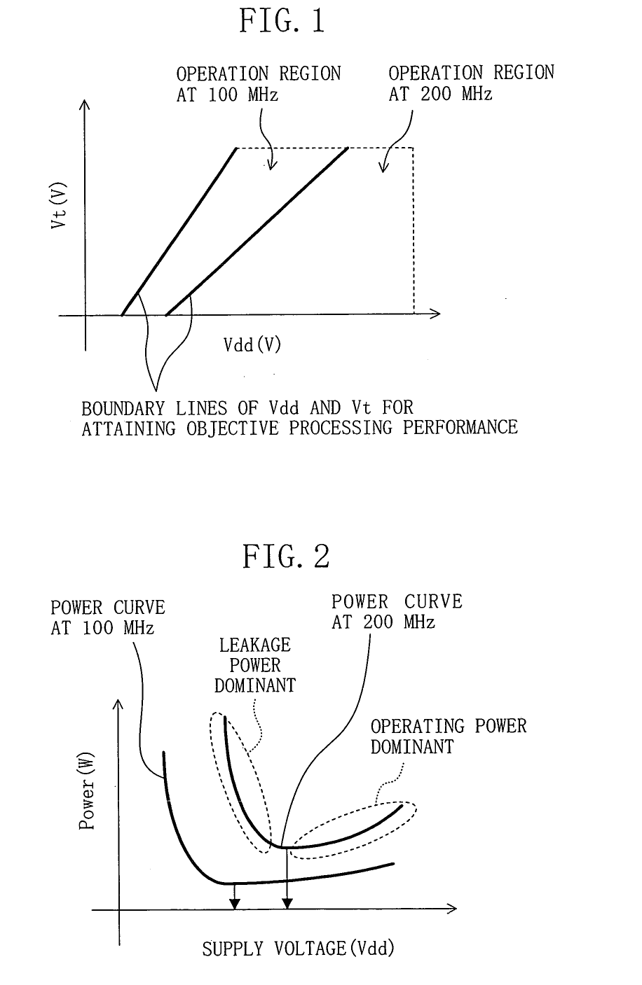

Specifically, a region of the supply voltage Vdd and the threshold voltage Vt satisfying Formula 4 corresponds to a region for attaining performance at the given frequency f. In FIG. 1, the ordinate indicates the supply voltage Vdd and the abscissa indicates the threshold voltage Vt of the MOS transistor. Thus, FIG. 1 shows an operation region for operating the MOS transistor at 200 MHz and an operation region for operating it at 100 MHz. In this manner, when the same semiconductor circuit is operated faster, it is necessary to increase the supply voltage Vdd or lower the threshold voltage Vt. Also, it is understood from this graph that when the operation supply voltage Vdd is determined, there is one highest threshold voltage Vt necessary for the operation.

Power Consumption Theory

Next, power consumption determined by the supply voltage Vdd and the threshold voltage Vt will be described.

In general, in a MOS semiconductor circuit, the power consumption is roughly divided into two components. One is designated as operating power or activating power, which is generated through charge/discharge of parasitic capacitance, and the other is designated as static power or leakage power, which is caused by an off-leakage current of the MOS transistor. The activating power Pact can be approximated by the following Formula 5:
Pact=M·A·f·C·Vdd² Formula 5:
wherein M is the total number of transistors included in the semiconductor circuit, A is an average rate of MOS transistors charged/discharged per clock (namely, an operation probability per unit time, which will be hereinafter referred to as the operation probability), f is the operating frequency of the semiconductor circuit, and C is average parasitic capacitance per MOS transistor. As is understood from Formula 5, the activating power Pact has a power characteristic in proportion to a square of the supply voltage Vdd. Also, when the circuit configuration is determined, the values of M and A are uniquely determined, and when the layout and process are determined, the parameter C is uniquely determined. Accordingly, when the operating frequency f and the supply voltage Vdd are determined, the activating power Pact can be uniquely calculated.

On the other hand, the leakage power Pleak can be approximated by the following Formula 6:
Pleak=M·Vdd·Io·10^{(-(Vt-λVdd/s)} Formula 6:
wherein Io is a leakage current coefficient of the MOS transistor, s is a subthreshold coefficient and λ is a DIBL coefficient, all of which are parameters depending upon the process. It is said that a typical value of the subthreshold coefficient s is approximately 80 mV and that a typical value of the DIBL coefficient λis approximately 0.07. The leakage current, which is expressed as Io·10^{(-(Vt-λVdd/s)}, is an exponential function depending upon the threshold voltage Vt, and is abruptly increased as the threshold voltage Vt is lowered. Also, as described with respect to the operation speed theory, when the supply voltage Vdd is determined, there is one highest threshold voltage Vt for satisfying the operating frequency f. Accordingly, when the circuit configuration is determined, the number M is uniquely determined, and when the process is determined, the parameters Io, s and λ are determined and the highest threshold voltage Vt is determined in accordance with the supply voltage Vdd. Therefore, the leakage current corresponding to the supply voltage Vdd can be uniquely calculated in accordance with Formula 6.

Total power Pow can be calculated by adding the activating power Pact and the leakage power Pleak as represented by the following Formula 7:
Pow=M·A·f·C·Vdd²+M·Vdd·Io·10^{(-(Vt-λVdd/s)} Formula 7:

As is understood from the above description, when the supply voltage Vdd is set to be low, the highest threshold voltage Vt for satisfying the operating frequency f needs to be lower, and hence, the leakage power Pleak is exponentially increased. On the other hand, when the supply voltage Vdd is set to be high, the highest threshold voltage Vt for satisfying the operating frequency f can be set higher, and hence, the leakage power Pleak is negligible and the activating power Pact is dominant. Accordingly, it is understood from Formula 7 that there is a supply voltage Vdd for minimizing the total power Pow. FIG. 2 is a graph of the total power Pow obtained in accordance with Formula 7, wherein the ordinate indicates the supply voltage Vdd and the abscissa indicates the total power Pow corresponding to the supply voltage Vdd. It is noted that FIG. 2 shows two image diagrams respectively corresponding to the operation at 200 MHz and the operation at 100 MHz.

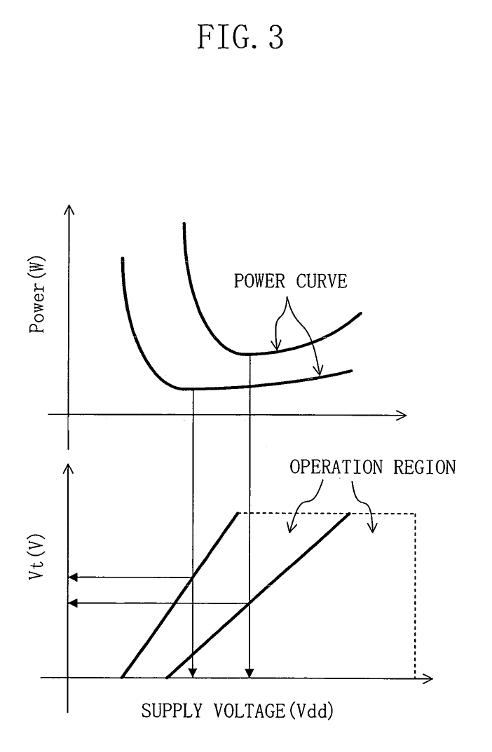

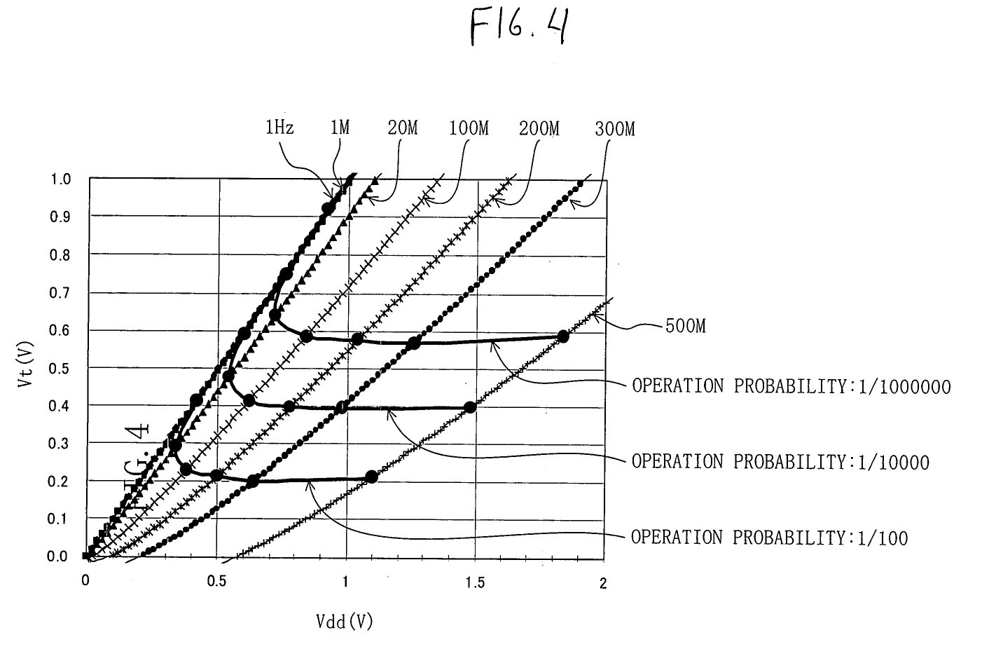

When the graphs of FIGS. 1 and 2 are used, a combination of the supply voltage Vdd and the threshold voltage Vt for minimizing the total power Pow can be obtained. FIG. 3 shows how to obtain the combination. On the basis of the power curve of FIG. 2, a supply voltage Vdd for minimizing the total power is obtained, and the thus obtained voltage is regarded as the supply voltage of FIG. 1 so as to obtain the highest threshold voltage Vt in the operation region of FIG. 1. It is thus understood that when the semiconductor device characteristics β, Io, λ and s, the operating frequency f, the average value C of the parasitic capacitance, the operation probability A, the maximum number G of gate stages between clocks are determined, there is merely one combination of the supply voltage Vdd and the threshold voltage Vt for minimizing the total power Pow.

Analysis Using Actual Semiconductor Parameters

Results obtained through an analysis performed on the basis of actual semiconductor MOS process parameters are shown in FIG. 4.

FIG. 4 is a graph for showing operation boundary regions between the supply voltage Vdd and the threshold voltage Vt obtained when the operation frequency is 1 Hz, 1 MHz, 20 MHz, 100 MHz, 200 MHz, 300 MHz and 500 MHz on the assumption that the maximum number of gate stages between clocks is 20. Furthermore, positions of the supply voltage Vdd and the threshold voltage Vt for realizing minimum power with respect to operation probabilities of 1/100, 1/10000and 1/1000000 at each operating frequency are also plotted in FIG. 4. As is understood from FIG. 4, the threshold voltage Vt optimum for minimizing the total power Pow is largely varied depending upon the operation probability of the semiconductor circuit. Furthermore, in an operating frequency range between 100 MHz and 500 MHz, the optimum threshold voltage Vt is substantially constant.

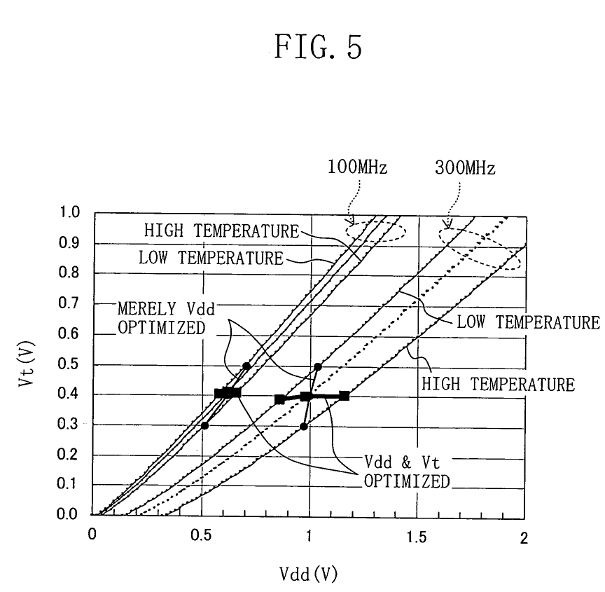

Next, loci of the optimum values of the supply voltage Vdd and the threshold voltage Vt through temperature change will be examined with reference to FIG. 5. It is known, in general, that when the temperature is higher than room temperature by approximately 60° C., the mobility μ is lowered and hence the coefficient β is reduced by approximately 20%. In FIG. 5, operation boundary lines obtained at a high temperature and a low temperature are added to the operation boundary lines of FIG. 4 obtained at room temperature when the operating frequency f is 100 MHz and 300 MHz. Furthermore, positions of the supply voltage Vdd and the threshold voltage Vt for realizing minimum power on the respective operation boundary lines are shown in FIG. 5 (with a symbol ▪). It is understood from FIG. 5 that the threshold voltage Vt for minimizing the total power is substantially constant also against the temperature change.

Comparison of Power Consumption with Conventional Technique

It is, however, known that the threshold voltage Vt is lowered by approximately 0.1 V at a high temperature and is increased by approximately 0.1 V at a low temperature in a general MOS device. Accordingly, the optimum combination of the supply voltage Vdd and the threshold voltage Vt cannot be realized through the optimization control of the supply voltage Vdd alone described with respect to the conventional technique.

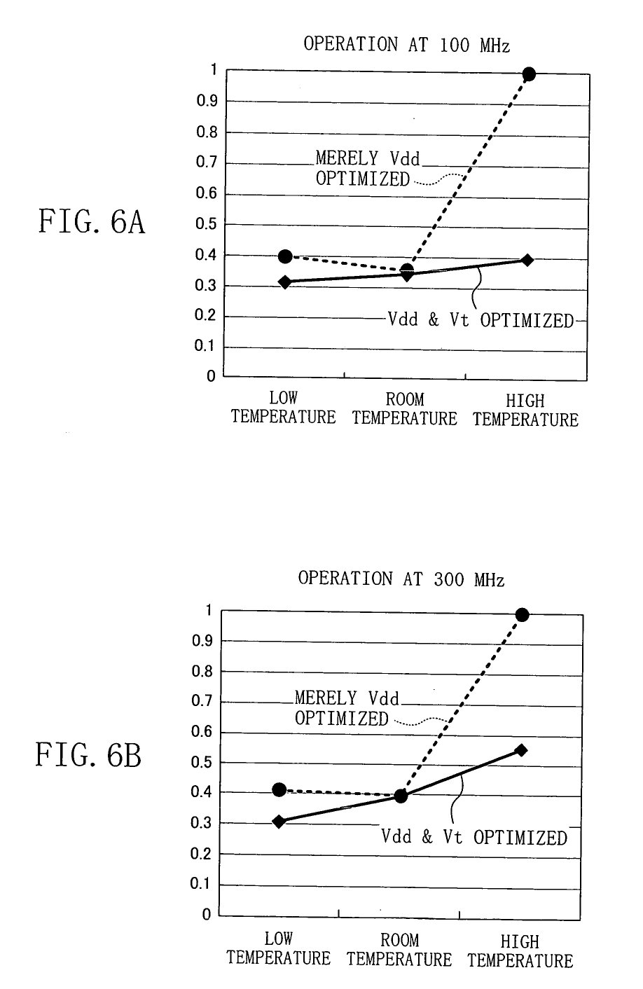

At this point, power consumed when the optimization is performed through the supply voltage control alone and power consumed when the optimization is performed through both the supply voltage control and the threshold voltage control will be compared. For example, in the case where the optimization is performed through the supply voltage control alone, it is assumed that the supply voltage Vdd and the threshold voltage Vt are set to their optimum values at room temperature. In this case, the threshold voltage Vt is lowered by 0.1 V at a high temperature and is increased by 0.1 V at a low temperature, and therefore, in order to minimize the supply voltage Vdd, the device is operated at a supply voltage minimized correspondingly to the thus changed threshold voltage Vt. Referring to FIG. 5, when the operating frequency f is 300 MHz or 100 MHz, a vertical line extending between black circles corresponds to optimum points obtained by the optimization through the supply voltage control alone. The total power obtained when the device is operated at these operation points and that obtained when it is operated at actual optimum points are compared in FIGS. 6A and 6B, wherein the abscissa indicates the temperature and the ordinate indicates a relative value of power normalized by regarding the maximum power out of those obtained at the respective operation points as 1. As is understood from FIGS. 6A and 6B, as compared with the case where the supply voltage Vdd alone is optimized, the total power can be reduced by approximately 50% at a high temperature and by approximately 25% at a low temperature by optimization control of both the supply voltage Vdd and the threshold voltage Vt.

Realized Circuits

On the basis of the aforementioned analysis results, the optimization control of the supply voltage Vdd and the threshold voltage Vt for minimizing the total power Pow can be realized through the following procedures:
(1) The threshold voltage Vt is determined in accordance with the operation probability of a semiconductor circuit.
(2) The threshold voltage Vt of the semiconductor circuit is controlled to be substantially constant against the temperature change.
(3) The supply voltage Vdd is controlled so as to satisfy a desired operation speed.

Now, a circuit architecture for realizing the aforementioned concept will be described.

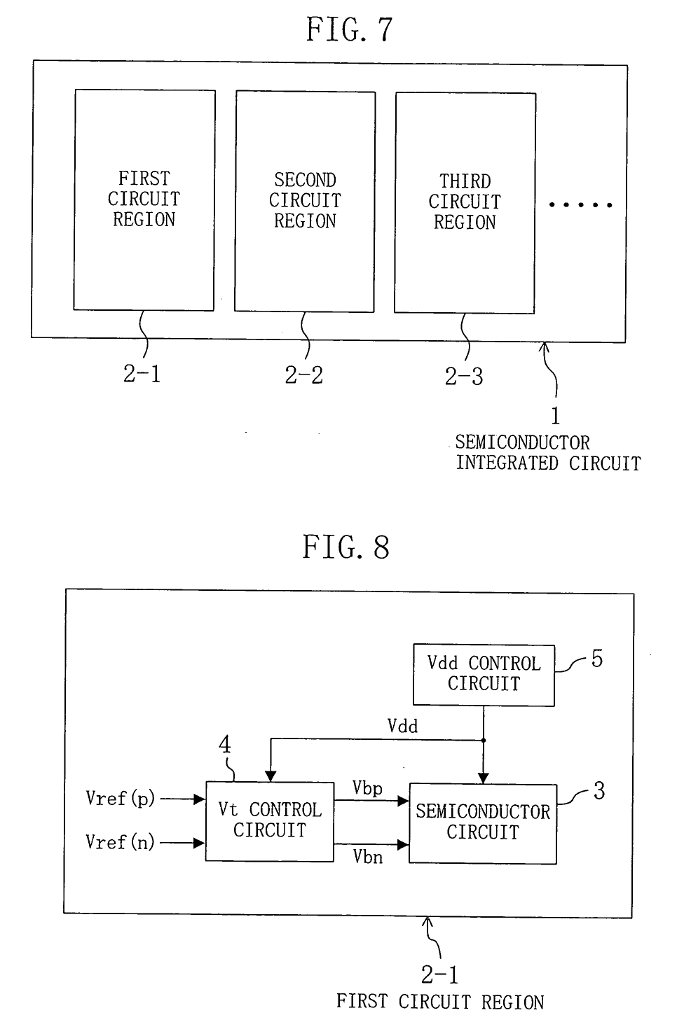

FIG. 7 shows a semiconductor integrated circuit based on the present invention. In FIG. 7, a reference numeral 1 denotes the whole semiconductor integrated circuit. The semiconductor integrated circuit 1 includes a large number of semiconductor circuits not shown. Regions of these semiconductor circuits are partitioned in accordance with their operation probabilities, and one or more semiconductor circuits having substantially the same operation probability are collected in one region. In FIG. 7, reference numerals 2-1, 2-2 and 2-3 denote three circuit regions thus partitioned. Typical examples of semiconductor circuits having different operation probabilities are a memory circuit, a logic circuit and a clock circuit system. The operation probability of a memory circuit is merely 1/1000000 even when data access is made in every operation if the memory circuit has a 1 M address space. On the other hand, the operation probability of a clock circuit system (for example, a clock buffer or a latch circuit) is approximately 1 because a clock signal is input in every operation. Also, it is said that the operation probability of a logic circuit such as an operator is 1/100 through 1/1000 depending upon the state of a program. Accordingly, in FIG. 7, the whole region is partitioned into the three regions, and as a result, for example, the first circuit region 2-1 includes logic circuits, the second circuit region 2-2 includes memory circuits and the third circuit region 2-3 includes clock circuit systems.

As significant concepts of the present invention, in each of the thus partitioned circuit regions 2-1 through 2-3, the optimization control of the supply voltage Vdd and the threshold voltage Vt is performed on semiconductor circuits included therein.

FIG. 8 shows an exemplified architecture in which the supply voltage Vdd and the threshold voltage Vt are both controlled in semiconductor circuits (for example, logic circuits) included in, for example, the first circuit region 2-1 independently of the other circuit regions 2-2 and 2-3. In FIG. 8, a reference numerals 3 denotes a semiconductor circuit (for example, a logic circuit) for realizing an actual function, a reference numeral 4 denotes a Vt control circuit (a threshold voltage control circuit), and a reference numeral 5 denotes a Vdd control circuit (a supply voltage control circuit). In the semiconductor circuit 3, threshold voltages Vtn and Vtp of n-type and p-type MOS transistors included therein are controlled through substrate voltage control using substrate voltages Vbn and Vbp supplied by the Vt control circuit 4. Also, the supply voltage of the semiconductor circuit 3 is controlled in accordance with a supply voltage Vdd supplied by the Vdd control circuit 5.

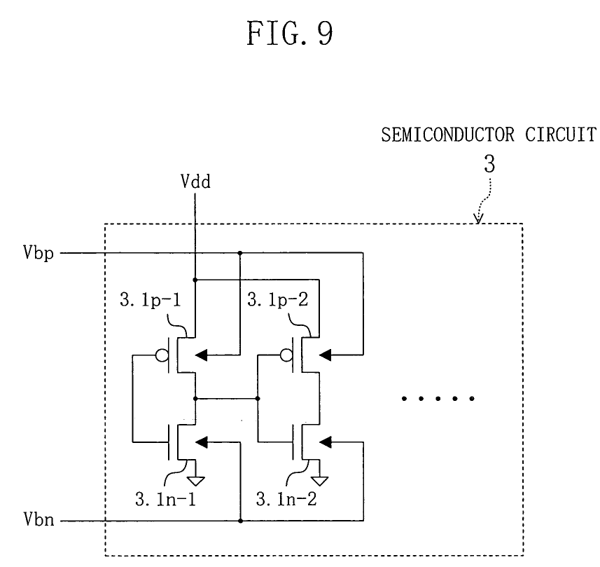

The semiconductor circuit 3 is composed of, for example, a plurality of n-type MOS transistors 3.1n-1 and 3.1n-2 and p-type MOS transistors 3.1p-1 and 3.1p-2 as shown in FIG. 9. The threshold voltage Vtn of the n-type MOS transistors 3.1n-1 and 3.1n-2 is controlled in accordance with the substrate voltage Vbn supplied by the Vt control circuit 4, and the threshold voltage Vtp of the p-type MOS transistors 3.1p-1 and 3.1p-2 is controlled in accordance with the substrate voltage Vbp supplied by the Vt control circuit 4. Also, the semiconductor circuit 3 is controlled in its supply voltage Vdd in accordance with the supply voltage Vdd supplied by the Vdd control circuit 5.

At this point, the relationship between the threshold voltage Vt and the substrate voltage Vb of a MOS transistor is represented by the following Formula 8:
Vt=Vto+γ({square root over ((B−Vb)))} Formula 8:
wherein Vto, B and γ are constants in accordance with the successfulness of the process, and Vb is a voltage difference between the source of the MOS transistor and the substrate, which is designated as the substrate voltage. It is understood from Formula 8 that the threshold voltage Vt is increased and reduced respectively by controlling the substrate voltage Vb to be a negative voltage and a positive voltage. Thus, the threshold voltage Vt can be controlled in accordance with the substrate voltage Vb.

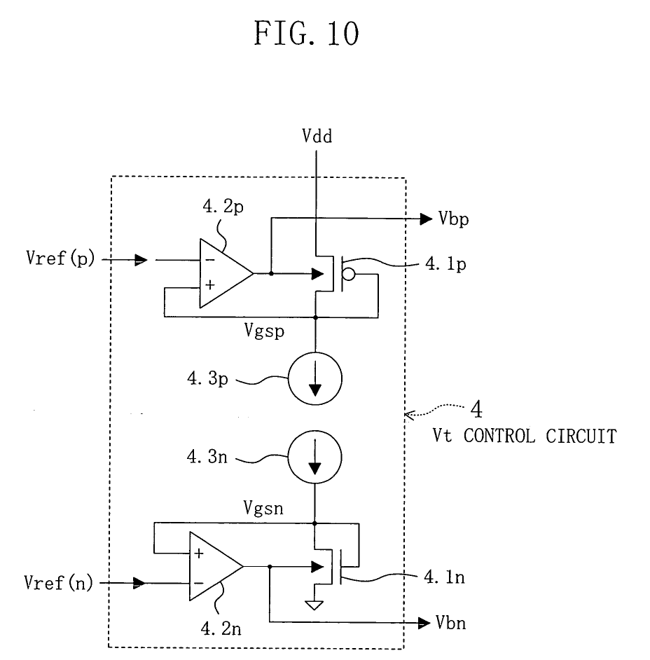

FIG. 10 shows an example of the circuit configuration of the Vt control circuit 4. In FIG. 10, a reference numeral 4.1p denotes a p-type MOS transistor, a reference numeral 4.1n denotes an n-type MOS transistor, reference numerals 4.2p and 4.2n denote operational amplifiers, and reference numerals 4.3p and 4.3n denote constant current sources. It is assumed herein that the threshold voltage Vt is defined as, for example, a gate-source voltage Vgs obtained by allowing a current of 50 nA to flow per unit gate width of the MOS transistor. In this case, a constant current with a current value according to the gate width of the MOS transistor 4.1 is allowed to flow to the constant current source 4.3. Significantly in this example, reference voltages of the threshold voltages Vt determined correspondingly to the operation probability of the semiconductor circuit 3 are given respectively to the operational amplifiers 4.2p and 4.2n as target threshold voltages Vref(n) and Vref(p). For example, in the case where the semiconductor circuit 3 is a logic circuit and its operation probability is 1/100, assuming that the ordinate of FIG. 4 indicates the threshold voltage Vt of a p-type MOS transistor, a reference voltage of 0.2 V is given as the target threshold voltage Vref(p). It is noted that although the target threshold voltage Vref(n) is a reference voltage on the basis of a ground voltage Vss, the target threshold voltage Vref(p) should be a reference voltage on the basis of the supply voltage Vdd.

In the Vt control circuit 4 shown in FIG. 10, the gate-source voltages Vgsn and Vgsp of the n-type and p-type MOS transistors 4.1n and 4.1p are defined as the threshold voltages Vtn and Vtp, and the substrate voltages of the p-type and n-type MOS transistors 4.1n and 4.1p are feedback controlled so as to make the threshold voltages Vtn and Vtp respectively equal to the reference voltages Vref(n) and Vref(p). Accordingly, even when the threshold voltages Vtn and Vtp of the transistors 4.1n and 4.1p are varied due to the temperature change or the process variation, the Vt control circuit 4 of FIG. 10 can control to make the target threshold voltages Vref(n) and Vref(p) substantially constant. The substrate voltages Vbp and Vbn generated by the Vt control circuit 4 are also supplied as the substrate voltages of the n-type and p-type MOS transistors included in the semiconductor circuit 3 shown in FIG. 9.

The target threshold voltages Vref(n) and Vref(p) are used for setting the threshold voltage Vt in each circuit region partitioned in accordance with the operation probability. Therefore, as described with respect to the analysis and with reference to FIG. 4, these target threshold voltages are determined in accordance with the operation probability of the semiconductor circuits included in the corresponding region, and are set to low threshold voltages when the operation probability is high and set to high threshold voltages when the operation probability is low as described above. It is noted that the target threshold voltage Vref preferably minimally depends upon the temperature. Furthermore, a finely adjustable trimming function is preferably provided for reducing the variation of the target threshold voltage Vref itself, or a function for changing the set value is preferably additionally provided in consideration of a difference of the operation probability from an actual probability value and a difference in the successfulness of the process.

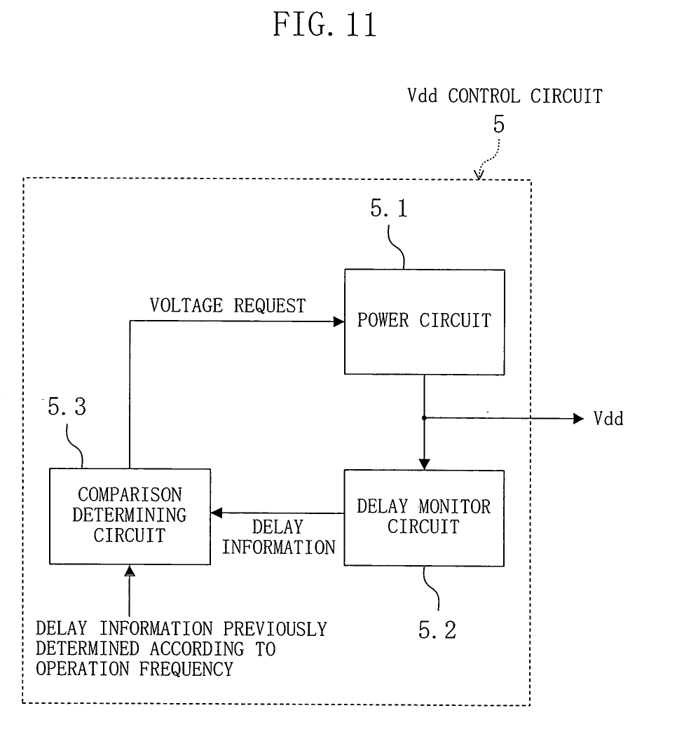

Next, an example of the circuit architecture of the Vdd control circuit 5 will be described. The Vdd control circuit 5 that controls the supply voltage Vdd for the semiconductor circuit 3 so as to make the semiconductor circuit 3 operated at a given operating frequency may have any of several architectures, one of which is shown in FIG. 11.

In FIG. 11, a reference numeral 5.1 denotes a power circuit for generating the supply voltage Vdd for the semiconductor circuit 3 on the basis of voltage request information, a reference numeral 5.2 denotes a delay monitor circuit having an internal circuit with a delay changed in accordance with the supply voltage Vdd supplied from the power circuit 5.1, and the delay of the delay monitor circuit 5.2 is substantially equal to the delay of a critical path included in the semiconductor circuit 3. A reference numeral 5.3 denotes a comparison determining circuit that compares delay information (the delay) supplied by the delay monitor circuit 5.2 with delay information previously determined correspondingly to the operating frequency of the semiconductor circuit 3 and stored in its own circuit region and makes a voltage request of the power circuit 5.1. The delay information of the delay monitor circuit 5.2 is increased/reduced in accordance with the supply voltage Vdd supplied by the power circuit 5.1. Accordingly, the power circuit 5.1 controls the supply voltage Vdd so that the delay information of the delay monitor circuit 5.2 can accord with the delay information (target delay) stored in its own circuit region and corresponding to the operating frequency of the semiconductor circuit 3.

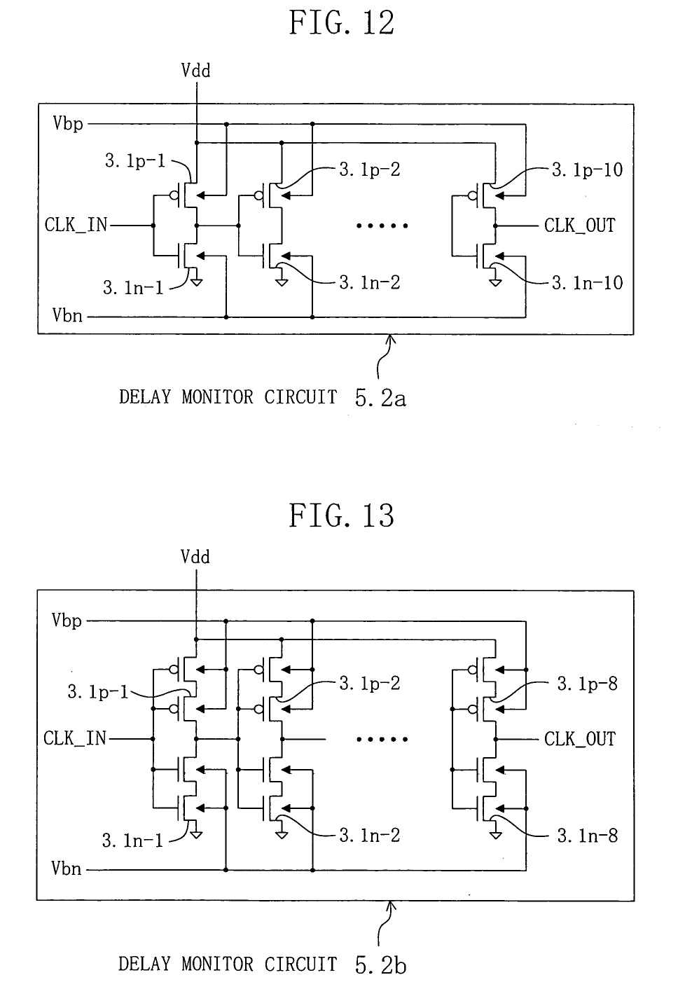

The delay monitor circuit 5.2 may have a circuit configuration equivalent to that of a circuit forming critical path delay of the semiconductor circuit 3. A specific example of the configuration of the delay monitor circuit 5.2 is shown in FIG. 12. A delay monitor circuit 5.2a of FIG. 12 includes ten p-type MOS transistors 3.1p-1 through 3.1p-10 and ten n-type MOS transistors 3.1n-1 through 3.1n-10, and pairs each of one n-type MOS transistor and one p-type MOS transistor are serially connected so as to serially connect ten inverter circuits. The substrate voltages of these p-type and n-type MOS transistors are controlled by the above-described Vt control circuit 4, and a phase difference between a clock signal CLK-IN input to the inverter circuit disposed at the first stage and a clock signal CLK-OUT output from the inverter circuit disposed at the last stage is output as the delay information. Also, FIG. 13 shows a delay monitor circuit 5.2b having another configuration. In the delay monitor circuit 5.2b of FIG. 13, eight inverter circuits each composed of two p-type MOS transistors and two n-type MOS transistors are serially connected to each other.

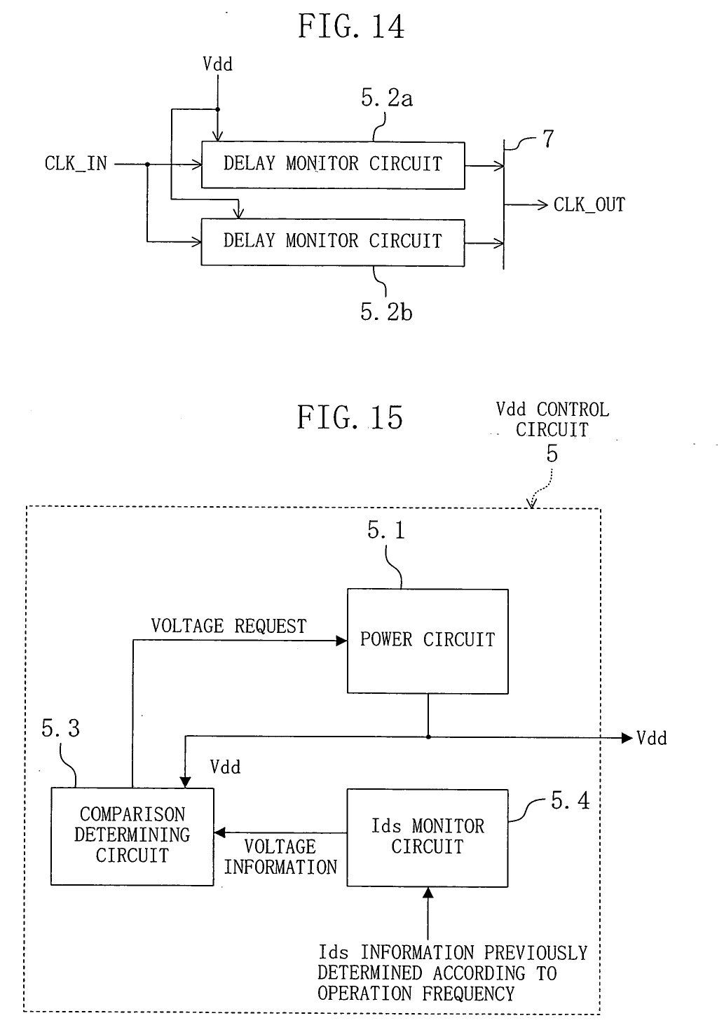

In the case where the Vdd control circuit 5 includes a plurality of delay monitor circuits having different configurations as the two delay monitor circuits 5.2a and 5.2b shown in FIGS. 12 and 13, one of the delay monitor circuits is selected by a selector 7 as shown in FIG. 14. For example, in the case where the threshold voltage Vt of the semiconductor circuit 3 is set to high or the supply voltage is lowered, the delay characteristic of the critical path of the semiconductor circuit 3 may become closer to that of the delay monitor circuit 5.2b of FIG. 13 than to that of the delay monitor circuit 5.2a of FIG. 12. In this case, the selector 7 is controlled so as to select the delay monitor circuit 5.2b of FIG. 13 having the delay characteristic closer to the critical path delay characteristic of the semiconductor circuit 3. In this manner, a plurality of kinds of delay monitor circuits are preferably prepared, so that a delay monitor circuit having a delay characteristic closer to the delay characteristic of an actual semiconductor circuit can be selected when the supply voltage Vdd is changed or the set value of the threshold voltage Vt is changed.

Alternatively, the delay monitor circuit 5.2 may be configured as a power control type ring oscillator. The delay monitor circuit 5.2 may employ any of the aforementioned configurations as far as the relationship between the supply voltage Vdd and the delay of the delay monitor circuit 5.2 is equivalent to the relationship between the supply voltage and the delay of the semiconductor circuit 3. It is preferred that the delay monitor circuit 5.2 uses the MOS transistors used in the semiconductor circuit 3 and that the substrate voltages Vbn and Vbp of these MOS transistors are equal to those of the semiconductor circuit 3. Also, the comparison determining circuit 5.3 may be configured by an analog circuit so as to output the voltage request information as an analog reference voltage, or may be configured by a digital circuit so as to output the voltage request information as updown information of the output voltage of the power circuit 5.1 or digital value information of the output voltage.

The Vdd control circuit 5 shown in FIG. 11 performs feedback control so that the delay information supplied from the delay monitor circuit 5.2 can accord with the target delay information input to the comparison determining circuit 5.3 (that is, the delay information corresponding to the operating frequency of the semiconductor circuit 3). In this manner, the supply voltage Vdd of the semiconductor circuit 3 is always controlled to attain a given delay satisfying the operating frequency of the semiconductor circuit 3, and therefore, the necessary and sufficient minimum supply voltage Vdd is always supplied to the semiconductor circuit 3.

FIG. 15 shows another example of the architecture of the Vdd control circuit 5. In FIG. 15, a reference numeral 5.1 denotes a power circuit for generating the supply voltage Vdd for the semiconductor circuit 3 on the basis of the voltage request information. A reference numeral 5.4 denotes an Ids monitor circuit, which accepts Ids information (a target saturation current value) of MOS transistors previously determined correspondingly to the operating frequency of the semiconductor circuit 3 and converts a saturation current value Ids actually passing through a MOS transistor included therein into voltage information according to the device characteristic. A reference numeral 5.3 denotes a comparison determining circuit for comparing the supply voltage Vdd supplied by the power circuit 5.1 with the voltage information supplied by the Ids monitor circuit 5.4 and making a voltage request of the power circuit 5.1.

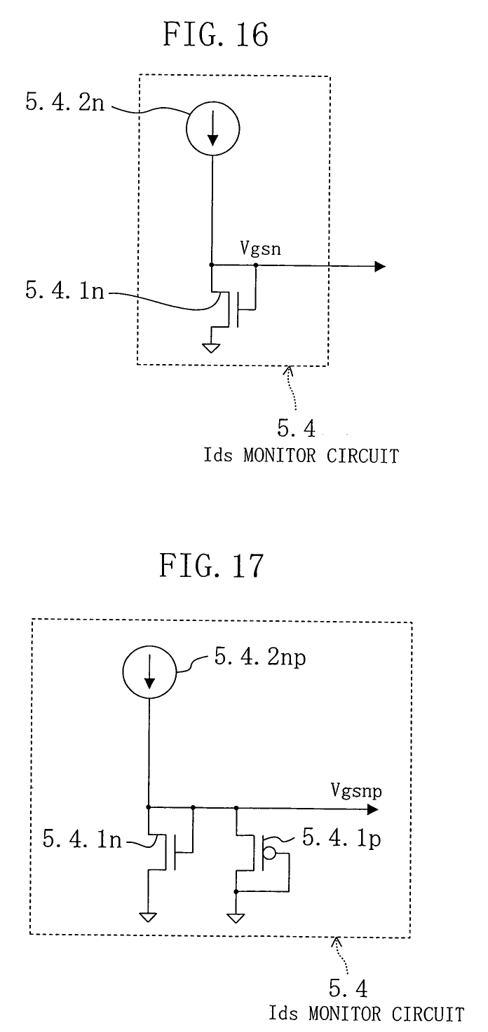

The Ids monitor circuit 5.4 of this Vdd control circuit 5 can be realized by using, for example, a circuit shown in FIG. 16. In FIG. 16, a reference numeral 5.4.1n denotes an n-type MOS transistor, and a reference numeral 5.4.2n denotes a constant current source for supplying a current based on the Ids information (target Ids value) previously determined correspondingly to the operating frequency of the semiconductor circuit 3. When the constant current is allowed to flow from the constant current source 5.4.2n to the transistor 5.4.1n configured as a MOS diode, the constant current is converted into voltage information Vgsn according to the Ids information and the characteristic of the MOS transistor 5.4.1n. When the voltage information Vgsn is lower than the output voltage Vdd of the power circuit 5.1, it is determined that the current Ids passing through the MOS transistors included in the semiconductor circuit 3 is larger than the target Ids value, and hence, the comparison determining circuit 5.3 makes a voltage request of the power circuit 5.1 to lower the supply voltage Vdd. On the contrary, when the voltage information Vgsn is higher than the output voltage Vdd of the power circuit 5.1, it is determined that the current Ids passing through the MOS transistors included in the semiconductor circuit 3 is smaller than the target Ids value, and hence, the comparison determining circuit 5.3 makes a voltage request of the power circuit 5.1 to increase the supply voltage Vdd. Accordingly, the feedback control is performed so as to make the output voltage Vdd of the power circuit 5.1 equal to the voltage information Vgsn supplied by the Ids monitor circuit, and ultimately, the output voltage Vdd becomes equal to the voltage information Vgsn. Specifically, the current Ids of the n-type MOS transistor 5.4.1n of the Ids monitor circuit 5.4 becomes equal to the target current Ids previously determined correspondingly to the operating frequency of the semiconductor circuit 3.

The configuration of the Ids monitor circuit 5.4 can be variously modified. For example, with respect to variation of the delay of the semiconductor circuit 3, in the case where variation derived from the Ids characteristic variation of the p-type MOS transistor is dominant, the n-type MOS diode 5.4.1n of the Ids monitor circuit 5.4 of FIG. 16 may be replaced with a p-type MOS diode. Alternatively, when an average value of the currents Ids of the n-type and p-type MOS transistors is dominant in the whole delay of the semiconductor circuit 3, an n-type MOS diode 5.4.1n and a p-type MOS diode 5.4.1p are connected in parallel and a constant current having a value corresponding to the sum of the target current values Ids of the n-type and p-type MOS transistors is allowed to flow from a constant current source 5.4.2np as shown in FIG. 17. The Ids monitor circuit 5.4 may have any of the aforementioned configurations as far as the relationship between the supply voltage Vdd and the transistor current Ids is equivalent to the relationship between the supply voltage Vdd of the semiconductor circuit 3 and the current Ids determining the delay of the semiconductor circuit 3. It is preferred that the Ids monitor circuit 5.4 uses the MOS transistors used in the semiconductor circuit 3 and that the substrate voltages of these MOS transistors are equal to those of the MOS transistors of the semiconductor circuit 3. The comparison determining circuit 5.3 may be configured by an analog circuit so as to output the voltage request information as an analog reference voltage, or may be configured by a digital circuit so as to output the voltage request information as updown information of the output voltage of the power circuit 5.1 or digital value information of the output voltage.

When the Vdd control circuit 5 has the architecture shown in FIG. 15, the parameter Ids used for determining the delay of the semiconductor circuit 3 can be controlled to be always constant without depending upon the temperature change or the fabrication process variation. At this point, the Ids information previously determined correspondingly to the operating frequency of the semiconductor circuit 3 is preferably Ids information in proportion to the supply voltage Vdd. This is because the delay of the semiconductor circuit 3 can be approximated by the aforementioned Formula 1, and hence, the saturation current value Ids in proportion to the supply voltage Vdd is necessary for obtaining the same delay.

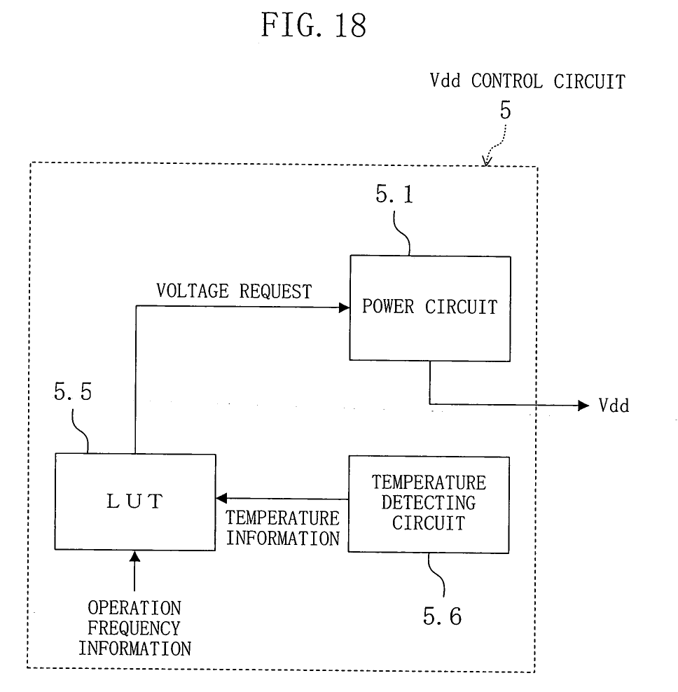

FIG. 18 shows another example of the architecture of the Vdd control circuit 5. In FIG. 18, a reference numeral 5.1 denotes a power circuit for generating the supply voltage Vdd for the semiconductor circuit 3 on the basis of the voltage request information, a reference numeral 5.6 denotes a temperature detecting circuit for detecting the temperature within the semiconductor circuit 3, and a reference numeral 5.5 denotes an LUT (Look Up Table) used for generating necessary voltage information on the basis of the temperature information supplied by the temperature detecting circuit 5.6 and the operating frequency information of the semiconductor circuit 3. In FIG. 18, the supply voltage Vdd necessary for the semiconductor circuit 3 is stored in the LUT 5.5 on a matrix of the operating frequency and the operation temperature of the semiconductor circuit 3 at the time of design or delivery inspection. In this example, when the information is input to the LUT 5.5 on the basis of the temperature information and the operating frequency information alone, the necessary voltage request information is immediately transferred to the power circuit 5.1.

The Vdd control circuit 5 of FIG. 11 or 15 performs the feedback control but the Vdd control circuit 5 of FIG. 18 performs feedforward control. The former Vdd control circuit 5 automatically adjusts all the parameters necessary for obtaining the delay so as to obtain the optimum voltage, and in this Vdd control circuit, the correlation accuracy between the delay monitor circuit 5.2 or the Ids monitor circuit 5.4 and the critical path delay of the semiconductor circuit 3 and a speed of response to the change of the temperature or the operating frequency are significant. However, in the Vdd control circuit 5 of FIG. 18, when the supply voltage is stored in the LUT 5.5 on the matrix of the operating frequency and the operation temperature at the time of delivery, the supply voltage Vdd can be adjusted to the optimum voltage equivalent to that attained by the exemplified architecture of the former Vdd control circuit 5. In the case where the LUT 5.5 is prepared at the stage of design, it is preferred to secure a variety of margins of the supply voltage Vdd for a simulation error, the process variation of the coefficient β and the like.

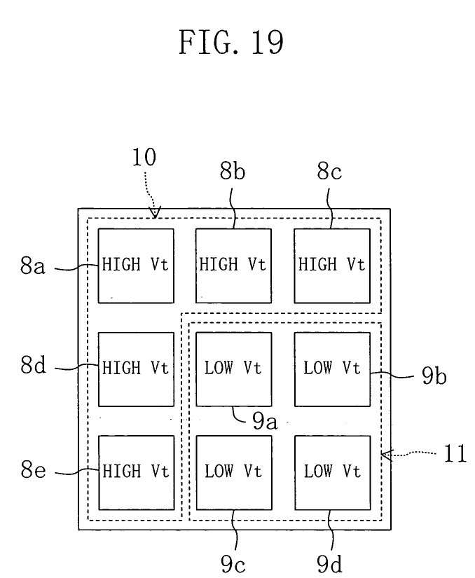

FIG. 19 shows the rough arrangement of the semiconductor circuits included in the semiconductor integrated circuit according to the embodiment of the invention. In FIG. 19, eight semiconductor circuits 8a through 8e disposed in a region 10 positioned along the left side and the upper side are fabricated through fabrication process in which the threshold voltage Vt of MOS transistors is set to a high threshold voltage, and four semiconductor circuits 9a through 9d disposed in the other region 11 are fabricated through fabrication process in which the threshold voltage Vt of MOS transistors is set to a low threshold voltage. In the case where the region (high threshold region) 10 and the region (low threshold region) 11 are previously partitioned in this manner, a semiconductor circuit such as a memory circuit with a low operation probability per unit time is fabricated in the region (high threshold region) 10 as, for example, the semiconductor circuit 8a, and on the other hand, a semiconductor circuit such as an operator or a clock circuit with a high operation probability per unit time is fabricated in the region (low threshold region) 11 as, for example, the semiconductor circuit 9b. Furthermore, in the case where a semiconductor circuit disposed in the high threshold region 10 (for example, the semiconductor circuit 8c) and a semiconductor circuit disposed in the low threshold region 11 (for example, the semiconductor circuit 9d) are processors with the identical circuit configuration, processing with a high operation probability per unit time on software is allocated to the processor 9d disposed in the low threshold region 11 and processing with a low operation probability per unit time is allocated to the processor 8c disposed in the high threshold region 10.

In this invention, it is not always necessary to build the Vt control circuit 4 and the Vdd control circuit 5 in the same semiconductor integrated circuit. For example, part of the functions such as those of various monitor circuits and a temperature detecting circuit are preferably integrated in the same semiconductor integrated circuit in particular, but if various characteristics of the semiconductor circuit 3 can be monitored with another chip, all the components of the Vdd control circuit 5 and the Vt control circuit 4 may be integrated on another chip.

As described so far, according to the semiconductor integrated circuit of this invention, respective semiconductor circuits are disposed in different regions partitioned in accordance with their operation probabilities per unit time, and in each of the regions, the optimization control of a supply voltage for semiconductor circuits included therein and the threshold voltage control of MOS transistors included therein are correlatively performed. Thus, the power consumption can be largely reduced. Accordingly, the semiconductor integrated circuit of the invention is useful as, for example, a semiconductor integrated circuit composed of MOS transistors and with low power consumption.

1. A semiconductor integrated circuit comprising:
a plurality of semiconductor circuits each of which is composed of a plurality of MOS transistors and which are disposed in regions partitioned in accordance with operation probabilities per unit time of said plurality of semiconductor circuits;
a threshold voltage control circuit provided to each of said regions for controlling a threshold voltage of MOS transistors used by a semiconductor circuit disposed in the corresponding region; and
a supply voltage control circuit provided to each of said regions for controlling a supply voltage supplied to a semiconductor circuit disposed in the corresponding region.

2. The semiconductor integrated circuit of claim 1,
wherein said threshold voltage control circuit controls a substrate voltage of said MOS transistors in such a manner that said threshold voltage of said MOS transistors is substantially constant against temperature change occurring in use, and
said supply voltage control circuit controls said supply voltage in such a manner that said semiconductor circuit disposed in the corresponding region attains a given operation speed.

3. The semiconductor integrated circuit of claim 2,
wherein said threshold voltage control circuit controls said threshold voltage of said MOS transistors in accordance with the operation probability of said semiconductor circuit disposed in the corresponding region.

4. The semiconductor integrated circuit of claim 2,
wherein said supply voltage control circuit controls said supply voltage in such a manner that actual delay of said semiconductor circuit disposed in the corresponding region accords with target delay at a given operating frequency of said semiconductor circuit.

5. The semiconductor integrated circuit of claim 4, further comprising, correspondingly to each of said regions, a plurality of delay monitor circuits with different architectures for monitoring actual delay of said semiconductor circuit disposed in the corresponding region,
wherein one of said plurality of delay monitor circuits is selected in accordance with a level of said threshold voltage of said MOS transistors controlled by said threshold voltage control circuit or a level of said supply voltage controlled by said supply voltage control circuit provided to the corresponding region.

6. The semiconductor integrated circuit of claim 2,
wherein said supply voltage control circuit controls said supply voltage in such a manner that an actual saturation current value of said MOS transistors used by said semiconductor circuit disposed in the corresponding region accords with a target saturation current value of said MOS transistors at a given operating frequency of said semiconductor circuit.

7. The semiconductor integrated circuit of claim 6,
wherein said target saturation current value is set to be in proportion to an actual operation supply voltage of said semiconductor circuit.

8. The semiconductor integrated circuit of claim 2,
wherein said supply voltage control circuit uniquely controls said supply voltage on the basis of operating frequency information of said semiconductor circuit disposed in the corresponding region and temperature information.

9. The semiconductor integrated circuit of claim 2,
wherein said plurality of semiconductor circuits are fabricated in a given region, and
said given region is previously partitioned into a high threshold region in which a threshold voltage of MOS transistors fabricated therein is high and a low threshold region in which a threshold voltage of MOS transistors fabricated therein is low.

10. The semiconductor integrated circuit of claim 9,
wherein a semiconductor circuit with a low operation probability per unit time is fabricated in said high threshold region and a semiconductor circuit with a high operation probability per unit time is fabricated in said low threshold region.

11. The semiconductor integrated circuit of claim 9,
wherein processors having an identical configuration are respectively fabricated in said high threshold region and said low threshold region, and
processing with a high operation probability per unit time is allocated to said processor fabricated in said low threshold region.
